(19) United States
(12) Patent Application Publication
(10) Pub. No.: US 2024/0149504 A1
(43) Pub. Date: May 9, 2024

(54) RESIN-SEALING METHOD AND RESIN-SEALING DEVICE

(71) Applicant: APIC YAMADA CORPORATION, Nagano (JP)

(72) Inventors: MASAHIKO FUJISAWA, Nagano (JP); MASASHI OKAMOTO, Nagano (JP); KAZUO ARAI, Nagano (JP)

(73) Assignee: APIC YAMADA CORPORATION, Nagano (JP)

(21) Appl. No.: 18/279,591

(22) PCT Filed: May 31, 2021
(86) PCT No.: PCT/JP2021/020674

§ 371 Date: Aug. 30, 2023

(51) Int. Cl. B29C 43/18; B29C 43/40

(52) U.S. Cl. CPC B29C 43/18; B29C 43/40; B29L 2031/34

(57) ABSTRACT

A resin-sealing method compression molds a resin on a workpiece having a plurality of components mounted on a carrier and manufactures a plurality of packages in each of which at least one of the components is sealed with the resin, the resin-sealing method including: setting a sheet resin in a resin molding die; and compression molding the sheet resin set in the resin molding die, wherein a penetrating hole is formed in a central portion of the sheet resin so that the amount of the resin is less in the central portion than in a peripheral portion of the sheet resin in plan view.

### TECHNICAL FIELD

The present invention relates to a resin-sealing method and a resin-sealing device.

### RELATED ART

As a method for manufacturing a package in which a component such as a semiconductor device is sealed with resin, the following method is known. That is, a resin is molded on a workpiece having a plurality of components mounted on a carrier, and a plurality of packages are collectively formed. One of such resin-sealing methods is a compression molding type.

Patent Document 1 discloses a resin supply method which is a method for supplying resin to a resin molding die of a compression molding type. The resin supply method includes steps of: while pressurizing a sheet resin so that a central portion of the sheet resin becomes convex and bending the sheet resin, pressing the sheet resin from the central portion of the sheet resin against an object to be supplied; and pressing the sheet resin against the object to be supplied toward an outer periphery of the sheet resin.

### PRIOR-ART DOCUMENTS

### Patent Documents

Patent Document 1: Japanese Patent Laid-open No. 2017-213725

### SUMMARY OF THE INVENTION

### Problems to be Solved by the Invention

However, in the resin supply method described in Patent Document 1, when the sheet resin is heated and compressed, while an end of the sheet resin flows to an outer edge of a cavity, the central portion of the sheet resin is unable to flow. Thus, the resin formed at an end of a workpiece may have a smaller thickness than the resin formed in a central portion of the workpiece, and packages manufactured from one workpiece may vary in dimensions.

The present invention has been made in view of such circumstances, and an object of the present invention is to provide a resin-sealing method and a resin-sealing device in which variation in package dimensions can be reduced.

### Means for Solving the Problems

A resin-sealing method according to one aspect of the present invention is a resin-sealing method that compression molds a resin on a workpiece having a plurality of components mounted on a carrier and manufactures a plurality of packages in each of which at least one component is sealed with resin. The resin-sealing method includes a step of setting a sheet resin in a resin molding die and a step of compression molding the sheet resin set in the resin molding die. At least one penetrating hole or recess is formed in a central portion of the sheet resin so that the amount of resin is less in the central portion of the sheet resin than in a peripheral portion of the sheet resin in plan view.

According to this aspect, since the at least one penetrating hole or recess is formed in the central portion of the sheet resin, the sheet resin that has been heated and compressed flows inward so as to fill the at least one penetrating hole or recess. Accordingly, variation in thickness of a molding resin molded on the workpiece is reduced. Thus, variation in dimensions of a plurality of packages formed from the workpiece can be reduced.

In the above aspect, the resin-sealing method may further include a step of feeding a resin film of an elongated shape, a step of cutting out the sheet resin from the resin film, and a step of forming the at least one penetrating hole or recess in the resin film or the sheet resin.

In the above aspect, the at least one penetrating hole may be formed by punching.

In the above aspect, the at least one penetrating hole may be formed by sucking an area where a cut has been made.

In the above aspect, a cavity of the resin molding die may have a circular shape. The sheet resin may have a rectangular shape whose diagonal length is equal to or less than a diameter of the cavity.

In the above aspect, the sheet resin may have a rectangular shape. The amount of decrease of resin in a portion along a diagonal line of the sheet resin due to the at least one penetrating hole or recess may be greater than the amount of decrease of resin in a portion along a bisector of each side of the sheet resin due to the at least one penetrating hole or recess.

In the above aspect, the at least one penetrating hole or recess may be one penetrating hole or recess. The one penetrating hole or recess and the sheet resin may be similar in shape in plan view.

In the above aspect, in the step of setting the sheet resin in the resin molding die, the sheet resin may be laminated on the workpiece to be sealed with resin.

In the above aspect, in the step of setting the sheet resin in the resin molding die, the sheet resin may be laminated on a release film.

A resin-sealing method according to another aspect of the present invention is a resin-sealing method that compression molds a resin on a workpiece having a plurality of components mounted on a carrier and manufactures a plurality of packages in each of which at least one component is sealed with resin. The resin-sealing method includes a step of setting a sheet resin in a resin molding die and a step of compression molding the sheet resin set in the resin molding die. A plurality of penetrating holes or recesses are formed over an entire surface of the sheet resin in plan view. An edge of the plurality of penetrating holes or recesses of the sheet resin set in the resin molding die overlaps any of the plurality of components.

According to this aspect, the amount of flow of the sheet resin that has been heated and compressed can be made uniform on the entire surface. Accordingly, variation in thickness of a molding resin molded on the workpiece can be reduced, and variation in dimensions of a plurality of packages formed from the workpiece can be reduced.

A resin-sealing device according to another aspect of the present invention is a resin-sealing device that compression molds a resin on a workpiece having a plurality of components mounted on a carrier and manufactures a plurality of packages in each of which at least one component is sealed with resin. The resin-sealing device includes: a sheet cutting part, cutting out a sheet resin from a resin film of an elongated shape; a reducing part, forming at least one penetrating hole or recess in the resin film or the sheet resin; and a resin molding die, compression molding the sheet resin that has been set. The at least one penetrating hole or recess is formed in a central portion of the sheet resin so that the amount of resin is less in the central portion of the sheet resin than in a peripheral portion of the sheet resin in plan view.

According to this aspect, since the at least one penetrating hole or recess is formed in the central portion of the sheet resin, the sheet resin that has been heated and compressed flows inward so as to fill the at least one penetrating hole or recess. Accordingly, variation in thickness of a molding resin molded on the workpiece is reduced. Thus, variation in dimensions of a plurality of packages formed from the workpiece can be reduced.

### Effects of the Invention

According to the present invention, a resin-sealing method and a resin-sealing device can be provided in which variation in package dimensions can be reduced.

### BRIEF DESCRIPTION OF THE DRAWINGS

FIG. 1 schematically illustrates a configuration of a resin-sealing device according to one embodiment.

FIG. 2 is a plan view schematically illustrating a configuration example of a sheet resin set in a resin molding die.

FIG. 3 is a flowchart schematically illustrating a resin-sealing method according to one embodiment.

FIG. 4 is a plan view schematically illustrating a modification of a sheet resin set in a resin molding die.

FIG. 5 is a plan view schematically illustrating a modification of a sheet resin set in a resin molding die.

FIG. 6 is a plan view schematically illustrating a modification of a sheet resin set in a resin molding die.

FIG. 7 is a plan view schematically illustrating a modification of a sheet resin set in a resin molding die.

FIG. 8 is a plan view schematically illustrating a modification of a sheet resin set in a resin molding die.

FIG. 9 is a plan view schematically illustrating a modification of a sheet resin set in a resin molding die.

FIG. 10 is a plan view schematically illustrating a modification of a sheet resin set in a resin molding die.

FIG. 11 schematically illustrates an example of a method for forming a penetrating hole.

FIG. 12 schematically illustrates an example of a method for forming a recess.

FIG. 13 schematically illustrates an example of a method for forming a recess.

### DESCRIPTION OF THE EMBODIMENTS

An embodiment of the present invention is hereinafter described with reference to the drawings. The drawings of the present embodiment are illustrative, and the dimensions or shapes of each part are schematic. The technical scope of the present invention should not be construed as being limited to the embodiment.

<Resin-Sealing Device>

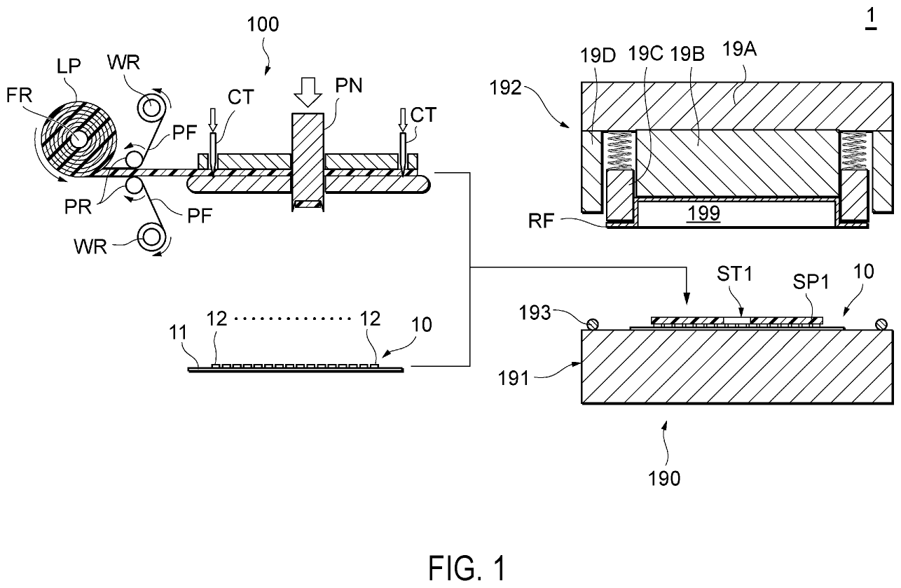

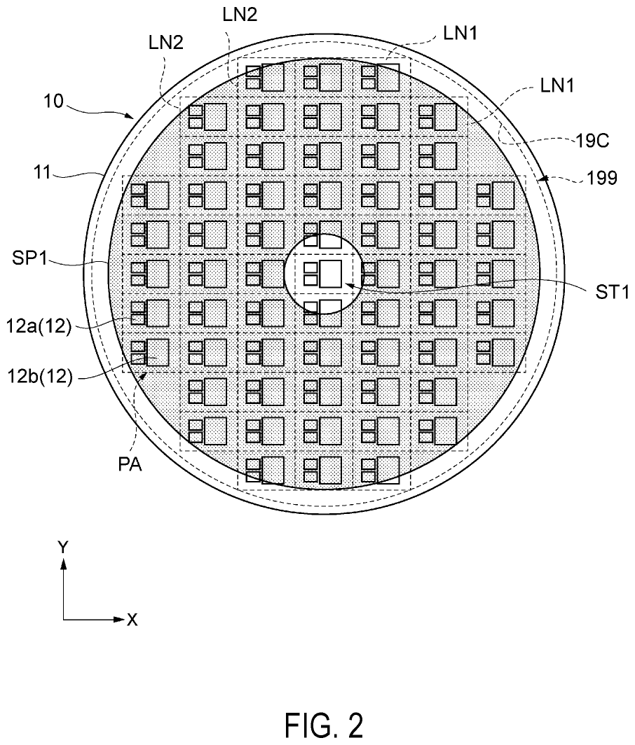

A configuration of a resin-sealing device 1 according to one embodiment of the present invention is described with reference to FIG. 1 and FIG. 2. FIG. 1 schematically illustrates a configuration of a resin-sealing device according to one embodiment. FIG. 2 is a plan view schematically illustrating a configuration example of a sheet resin set in a resin molding die.

The resin-sealing device 1 is a device that compression molds a resin on a workpiece 10 having a plurality of components 12 mounted on a carrier 11 and manufactures a plurality of packages in each of which at least one component 12 is sealed with resin (molded). The resin-sealing device 1 includes a resin supply device 100 that supplies a sheet resin SP1 and a resin molding die 190 that heats and compresses the sheet resin SP1. Here, the sheet resin SP1 is, for example, formed to have an arbitrary thickness by rolling a thermosetting resin such as an epoxy resin into a sheet.

As an example, the carrier 11 is a stainless steel carrier, and the component 12 is a semiconductor device (such as an integrated circuit (IC) chip, a diode, or a transistor) mounted on the carrier 11. However, the carrier 11 and the component 12 are not limited to the above. For example, the carrier 11 may be formed using a material such as resin, glass, metal, or semiconductor, and may be an interposer substrate, a lead frame, a carrier plate with an adhesive sheet, or the like. For example, the component 12 may be a microelectromechanical systems (MEMS) device or an electronic device (such as a capacitor, an inductor, or a resistor). The component 12 may be mounted on the carrier 11 by a wire bonding method or a flip chip method, or may be detachably fixed to the carrier 11. The component 12 includes, for example, two types of components, namely a component 12a and a component 12b. However, the component 12 may include a single component or may include three or more types of components.

The workpiece 10 is provided with a plurality of package areas PA demarcated by a plurality of division lines LN1 arranged side by side in an X-axis direction and a plurality of division lines LN2 arranged side by side in a Y-axis direction. The plurality of division lines LN1 and LN2 are imaginary lines for dividing the workpiece 10 on which resin is compression molded into a plurality of packages. The package area PA is an area to become a package. In the package area PA, for example, a plurality of components 12a and 12b are arranged.

The resin supply device 100 includes a feed roll FR, a pinch roll PR, a winding roll WR, a sheet cutter CT, and a mechanical punch PN.

The feed roll FR is a driving roll that feeds a resin film LP of an elongated shape from a resin roll around which the resin film LP is wound. The resin film LP fed by the feed roll FR has, for example, a protective film PF stuck on both sides thereof. The feed roll FR corresponds to an example of a film supply that supplies the resin film LP.

The pinch roll PR is a driving roll that transfers the fed resin film LP to the sheet cutter CT. The resin film LP is sandwiched by the pinch roll PR, and is transferred by rotation of the pinch roll PR. The resin film LP is fed, for example, by driving the feed roll FR and the pinch roll PR in conjunction with each other. The pinch roll PR corresponds to an example of a film transfer part that transfers the resin film LP.

The winding roll WR is a driving roll that peels the protective film PF from the resin film LP and winds the protective film PF. The winding roll WR corresponds to an example of a film peeling part that peels off the protective film PF.

The sheet cutter CT is a cutting machine that cuts out the sheet resin SP1 from the resin film LP from which the protective film PF has been removed. The sheet cutter CT corresponds to an example of a sheet cutting part that cuts out the sheet resin SP1 from the resin film LP. The sheet cutter CT may cut out the sheet resin SP1 by cutting once, or may cut out the sheet resin SP1 by cutting a plurality of times. In the case of cutting out the sheet resin SP1 by cutting a plurality of times, the sheet cutter CT may include, for example, a first sheet cutter that cuts the resin film LP and a second sheet cutter that cuts out the sheet resin SP1 from the resin film LP that has been cut. By the sheet cutter CT, the sheet resin SP1 may be cut out to have a circular or polygonal (such as octagonal or hexagonal) outer shape.

The mechanical punch PN is a punching machine that forms a penetrating hole ST1 by punching in the sheet resin SP1 cut out by the sheet cutter CT. The mechanical punch PN forms the penetrating hole ST1 in a central portion of the sheet resin SP1 so that the amount of resin is less in the central portion of the sheet resin SP1 than in a peripheral portion of the sheet resin SP1 in plan view. Accordingly, a portion where the amount of resin is small in a thickness direction is formed in the central portion of the sheet resin SP1. As illustrated in FIG. 2, there is, for example, one penetrating hole ST1 formed by the mechanical punch PN when the sheet resin SP1 is seen in plan view. However, the number of penetrating holes formed in the central portion of the sheet resin SP1 by the mechanical punch PN is not limited, and two or more penetrating holes may be formed. Two or more penetrating holes may be formed by punching once, or may be formed by punching a plurality of times. The mechanical punch PN corresponds to an example of a reducing part that forms at least one penetrating hole in the sheet resin SP1.

The mechanical punch PN may form at least one penetrating hole in the resin film LP before the sheet resin SP1 is cut out by the sheet cutter CT. In this case, the sheet cutter CT cuts out the sheet resin SP1 from the resin film LP so that at least one penetrating hole formed by the mechanical punch PN is located in the central portion of the sheet resin SP1. That is, the sheet resin SP1 is cut out from the resin film LP so that the amount of resin is less in the central portion of the sheet resin SP1 than in the peripheral portion of the sheet resin SP1 in plan view due to at least one penetrating hole.

The mechanical punch PN may form at least one penetrating hole at the same time as the sheet resin SP1 is cut out by the sheet cutter CT.

In the present embodiment, the mechanical punch PN that forms a penetrating hole is described as an example of a forming part. However, if the amount of resin is less in the central portion of the sheet resin SP1 than in the peripheral portion of the sheet resin SP1 in plan view, the forming part is not limited to a device that forms a penetrating hole. For example, the forming part may be a device that forms at least one recess in the sheet resin SP1 or the resin film LP.

The resin molding die 190 includes a pair of dies (lower die 191 and upper die 192) for sealing the workpiece 10 with resin using a compression molding technology. Of the lower die 191 and the upper die 192, a release film RF is set in the die having a cavity 199, and the workpiece 10 is set in the other die. The sheet resin SP1 is laminated on one of the release film RF and the workpiece 10 that is set in the lower die 191, and is set in the resin molding die 190. In the present embodiment, the resin molding die 190 has an upper die cavity structure having the cavity 199 in the upper die 192. Accordingly, the workpiece 10 and the sheet resin SP1 that is laminated on the workpiece 10 are set in the lower die 191. If the resin molding die 190 has a lower die cavity structure having the cavity 199 in the lower die 191, the workpiece 10 is set in the upper die 192, and the release film RF and the sheet resin SP1 laminated on the release film RF are set in the lower die 191.

The resin molding die 190 illustrated in FIG. 1 has a seal ring 193 (for example, an O-ring) that seals the inside (space between the lower die 191 and the upper die 192) of the resin molding die 190. Although not illustrated, the resin-sealing device 1 includes a pressure controller (for example, a vacuum pump) that adjusts the internal pressure of the resin molding die 190 or a temperature controller (for example, a heater) that adjusts the internal temperature (molding temperature) of the resin molding die 190.

The upper die 192 includes a chase 19A, a cavity block 19B fixed to the lower die 191 side of the chase 19A, a clamper 19C surrounding the cavity block 19B, and a chamber block 19D surrounding the clamper 19C at a spacing therefrom. The cavity block 19B is fixed to the lower die 191 side of the chase 19A. The clamper 19C protrudes toward the lower die 191 from the cavity block 19B, and forms the cavity 199 together with the cavity block 19B. The clamper 19C is connected to the chase 19A via a spring, and is configured to be slidable with respect to the cavity block 19B. When mold clamping is completed, an outer edge (carrier 11) of the workpiece 10 is sandwiched between the clamper 19C and the lower die 191. On a facing surface (surface facing the lower die 191) of the clamper 19C, a plurality of air vents are provided connecting a space on the chamber block 19D side and the cavity 199. The plurality of air vents are grooves provided radially about the cavity 199. The plurality of air vents function as exhaust holes that discharge air remaining in the cavity 199 of the resin molding die 190 that has been clamped or gas generated from the sheet resin SP1. The air vents are formed to a depth (for example, about several lam) that allows the air or gas to be discharged but does not allow the resin to flow out. The seal ring 193 contacts the chamber block 19D.

The sheet resin SP1 heated and compressed by the resin molding die 190 fills the cavity 199 and flows to have a uniform thickness. However, if a large amount of other resin exists in a direction in which the resin flows, the flowing of the resin may be hindered.

However, as illustrated in FIG. 2, when the sheet resin SP1 set in the resin molding die 190 is seen in plan view, a spacing is present between an edge of the sheet resin SP1 before being heated and compressed and an edge (clamper 19C) of the cavity 199. Accordingly, a surplus portion in the peripheral portion of the sheet resin SP1 that has been heated and compressed flows outward so as to fill the spacing. Since the penetrating hole ST1 is formed in the central portion of the sheet resin SP1, a surplus portion in the central portion of the sheet resin SP1 that has been heated and compressed flows inward so as to fill the penetrating hole ST1. In this way, in the case of the sheet resin SP1 in which the penetrating hole ST1 is formed, during heating and compression, the resin does not flow only in the peripheral portion, but in both the peripheral portion and the central portion in a well-balanced manner. Thus, a difference in thickness between the central portion and the peripheral portion of a molding resin molded on the workpiece 10 is reduced.

In the example illustrated in FIG. 2, the workpiece 10 and the cavity 199 have a circular shape and the sheet resin SP1 has a circular shape in plan view. The spacing between the sheet resin SP1 and the clamper 19C in a normal direction of the outer edge of the sheet resin SP1 is substantially equal in any direction within an XY plane. According to this, the amount of flow of the sheet resin SP1 outward in a direction (hereinafter referred to as “radial direction”) within the XY plane starting from the center of the sheet resin SP1 is substantially equal at any angle within the XY plane. The penetrating hole ST1 and the sheet resin SP1 are similar in shape, and the penetrating hole ST1 is formed in a circular shape. The penetrating hole ST1 and the sheet resin SP1 are concentrically circular. According to this, the amount of flow of the sheet resin SP1 inward in the radial direction is substantially equal at any angle within the XY plane. According to the above, variation in thickness of the molding resin depending on the angle in the radial direction may be reduced.

The size relationship or positional relationship between the penetrating hole ST1 and the component 12 are not particularly limited. For example, an edge of the penetrating hole ST1 partially overlaps the component 12 in plan view. The penetrating hole ST1 is provided over a plurality of package areas PA, and two or more components 12 are arranged inside the penetrating hole ST1.

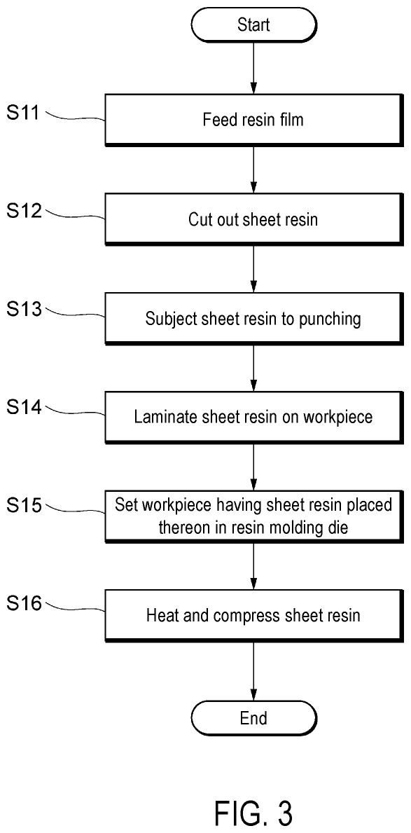

Next, an example of a resin-sealing method using the resin-sealing device 1 is described with reference to FIG. 3. FIG. 3 is a flowchart schematically illustrating a resin-sealing method according to one embodiment.

First, a resin film is fed (S11). A resin roll around which the resin film LP of an elongated shape is wound is set on the feed roll FR. Next, while the feed roll FR is driven to feed the resin film LP, the pinch roll PR is driven to transfer the resin film LP. At this time, the protective film PF is peeled from the resin film LP.

Next, the sheet resin SP1 is cut out (S12). The sheet resin SP1 is cut out from the resin film LP by the sheet cutter CT. In the case of the sheet resin SP1 of a circular shape, for example, first, the sheet cutter CT cuts the resin film LP into a rectangular shape by a first sheet cutter extending in a width direction of the resin film LP. Next, by a second sheet cutter extending in a circular shape, the sheet cutter CT cuts out the sheet resin SP1 from the resin film LP cut in a rectangular shape. The sheet cutter CT may also cut out the sheet resin SP1 directly from the resin film LP by cutting once.

Next, the sheet resin SP1 is subjected to punching (S13). The penetrating hole ST1 is formed in the sheet resin SP1 by the mechanical punch PN. The penetrating hole ST1 is formed in the central portion of the sheet resin SP1 so that the amount of resin is less in the central portion of the sheet resin SP1 than in the peripheral portion of the sheet resin SP1. The order of step S12 and step S13 may be reversed. That is, the penetrating hole ST1 may be formed in the resin film LP by the mechanical punch PN, and the sheet resin SP1 may be cut out so that the penetrating hole ST1 is located in the central portion.

Next, the sheet resin SP1 is laminated on the workpiece 10 (S14). The sheet resin SP1 is arranged inside the workpiece 10 in plan view. The sheet resin SP1 covers most of the plurality of components 12. The edge of the penetrating hole ST1, for example, partially overlaps the component 12, and two or more components 12 are arranged inside the penetrating hole ST1. Here, the sheet resin SP1 is arranged so as to have its center aligned with the center of the workpiece 10.

Next, the workpiece 10 having the sheet resin SP1 placed thereon is set in the resin molding die 190 (S15). The sheet resin SP1 is set together with the workpiece 10 in the lower die 191 of the resin molding die 190.

Finally, the sheet resin SP1 is heated and compressed (S16). The sheet resin SP1 accommodated in the cavity 199 in the resin molding die 190 that has been clamped is softened by heating. The softened sheet resin SP1 is compressed to be filled into a gap between the components 12, a gap between the carrier 11 and the component 12, or the like. At this time, the sheet resin SP1 flows so as to fill a gap between the sheet resin SP1 and the clamper 19C, or the penetrating hole ST1. When the resin compression molded from the sheet resin SP1 is cured, the resin molding die 190 is opened, and the workpiece 10 in which the component 12 is sealed with resin is taken out. The workpiece 10 taken out is divided along the plurality of division lines LN1 and LN2, and is separated into a plurality of packages.

As described above, by compression molding using the sheet resin SP1 having the penetrating hole ST1 formed in the central portion, when the sheet resin SP1 is heated and compressed, the amount of flow of the sheet resin SP1 in the peripheral portion and that in the central portion can be made uniform. Accordingly, a difference between the thickness of the resin molded into the central portion of the workpiece 10 and the thickness of the resin molded into the peripheral portion of the workpiece 10 can be reduced. That is, variation in dimensions of a plurality of packages manufactured from one workpiece 10 can be reduced.

Modifications of a sheet resin are described below. The matters common to the above embodiment can be applied in the same way in the following modifications and description thereof is omitted. Only different points are described. In particular, the same configurations are denoted by the same reference numerals, and description of the same configurations and the same effects resulting therefrom is not repeated.

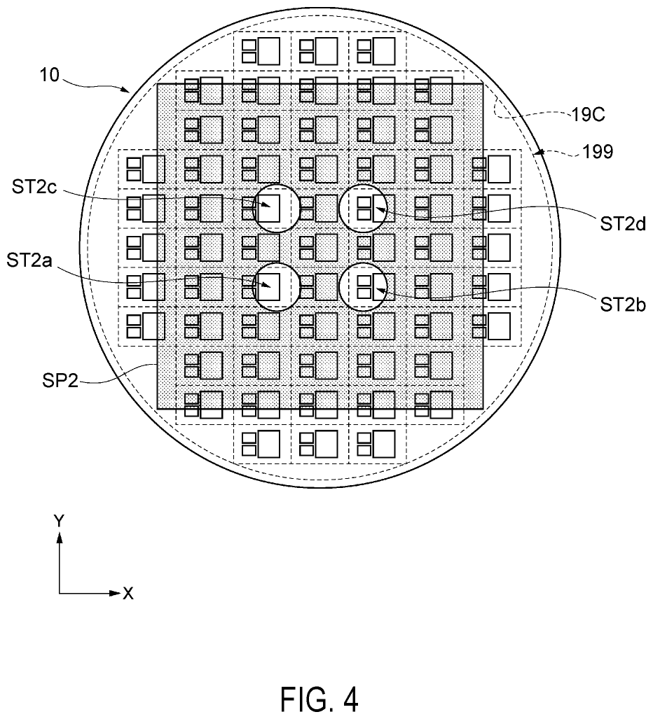

FIG. 4 is a plan view schematically illustrating a modification of a sheet resin set in a resin molding die. In plan view, a sheet resin SP2 is formed in a rectangular shape in contrast to the workpiece 10 and the cavity 199 both of a circular shape. The sheet resin SP2 is formed in, for example, a square shape having a set of sides extending in the X-axis direction and facing each other in the Y-axis direction and a set of sides extending in the Y-axis direction and facing each other in the X-axis direction. A diagonal length of the sheet resin SP2 is substantially equal to or slightly less than a diameter of the cavity 199. The sheet resin SP2 is closest to the edge (clamper 19C) of the cavity 199 at a corner and is farthest from the edge of the cavity 199 near a midpoint of each side. The sheet resin SP2 is, for example, cut out by a sheet cutter extending in a width direction of a resin film of an elongated shape. At this time, a width of the sheet resin SP2 is substantially equal to the width of the resin film.

In plan view, four penetrating holes of a circular shape, ST2a, ST2b, ST2c, and ST2d, are formed in a central portion of the sheet resin SP2. The penetrating holes ST2a, ST2b, ST2c, and ST2d are of substantially equal size. The penetrating holes ST2a, ST2b, ST2c, and ST2d are arranged in two columns and two rows along each side of the sheet resin SP2. Specifically, the penetrating hole ST2a and the penetrating hole ST2b are arranged side by side in the X-axis direction, and the penetrating hole ST2c and the penetrating hole ST2d are arranged side by side in the X-axis direction. The penetrating hole ST2a and the penetrating hole ST2c are arranged side by side in the Y-axis direction, and the penetrating hole ST2b and the penetrating hole ST2d are arranged side by side in the Y-axis direction. The penetrating hole ST2a and the penetrating hole ST2d are arranged side by side on one diagonal line of the sheet resin SP2, and the penetrating hole ST2b and the penetrating hole ST2c are arranged side by side on the other diagonal line of the sheet resin SP2. That is, the amount of resin in a portion along a diagonal line of the sheet resin SP2 decreases, and the amount of resin in a portion along a bisector of each side does not decrease. According to this, on the diagonal line of the sheet resin SP2 where a spacing between the edge of the sheet resin SP2 and the edge of the cavity 199 is small, a large amount of resin is able to flow inward during thermal compression; on the bisector of each side of the sheet resin SP2 where the spacing between the edge of the sheet resin SP2 and the edge of the cavity 199 is large, a large amount of resin is able to flow outward during thermal compression. Accordingly, it is possible to use the sheet resin SP2 of a rectangular shape for the cavity 199 of a circular shape, and loss of a resin film of a band shape that occurs when the sheet resin SP2 of a circular shape is cut from the resin film can be reduced. The penetrating holes ST2a, ST2b, ST2c, and ST2d may be arranged inclined at an angle of 45 degrees relative to, for example, the center of the sheet resin SP2 from the arrangement illustrated in FIG. 4, or may be arranged inclined at any angle.

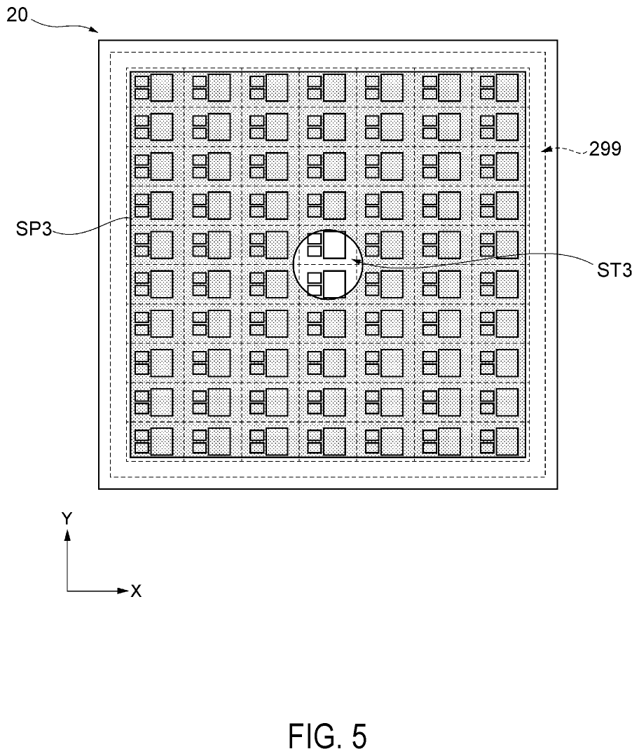

FIG. 5 is a plan view schematically illustrating a modification of a sheet resin set in a resin molding die. In plan view, a workpiece 20 and a cavity 299 are of a rectangular shape, and a sheet resin SP3 is similarly formed in a rectangular shape. The cavity 299 has a set of sides extending in the X-axis direction and facing each other in the Y-axis direction and a set of sides extending in the Y-axis direction and facing each other in the X-axis direction. The same applies to the sheet resin SP3. A spacing between an edge of the sheet resin SP3 and an edge of the cavity 299 on a plus (+) X-axis direction side of the workpiece 20 is substantially equal to a spacing between the edge of the sheet resin SP3 and the edge of the cavity 299 on a minus (−) X-axis direction side of the workpiece 20. A spacing between the edge of the sheet resin SP3 and the edge of the cavity 299 on a plus (+) Y-axis direction side of the workpiece 20 is substantially equal to a spacing between the edge of the sheet resin SP3 and the edge of the cavity 299 on a minus (−) Y-axis direction side of the workpiece 20. One penetrating hole ST3 of a circular shape is formed in a central portion of the sheet resin SP3.

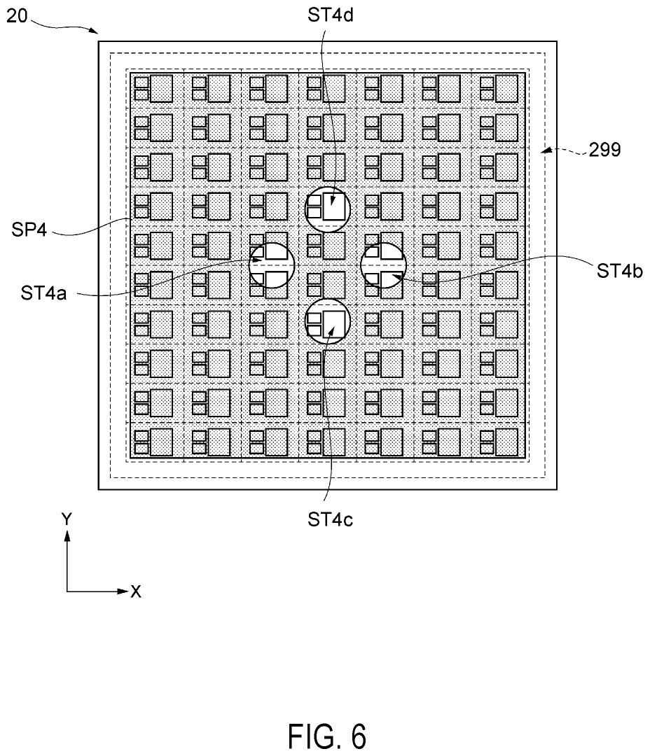

FIG. 6 is a plan view schematically illustrating a modification of a sheet resin set in a resin molding die. In plan view, a sheet resin SP4 is formed in a rectangular shape, like the sheet resin SP3 illustrated in FIG. 5. Four penetrating holes of a circular shape, ST4a, ST4b, ST4c and ST4d, are formed in a central portion of the sheet resin SP4. The penetrating holes ST4a to ST4d are of substantially equal size. The penetrating hole ST4a and the penetrating hole ST4b are arranged side by side on a bisector of a side of the sheet resin SP4 extending in the Y-axis direction. The penetrating hole ST4c and the penetrating hole ST4d are arranged side by side on a bisector of a side of the sheet resin SP4 extending in the X-axis direction.

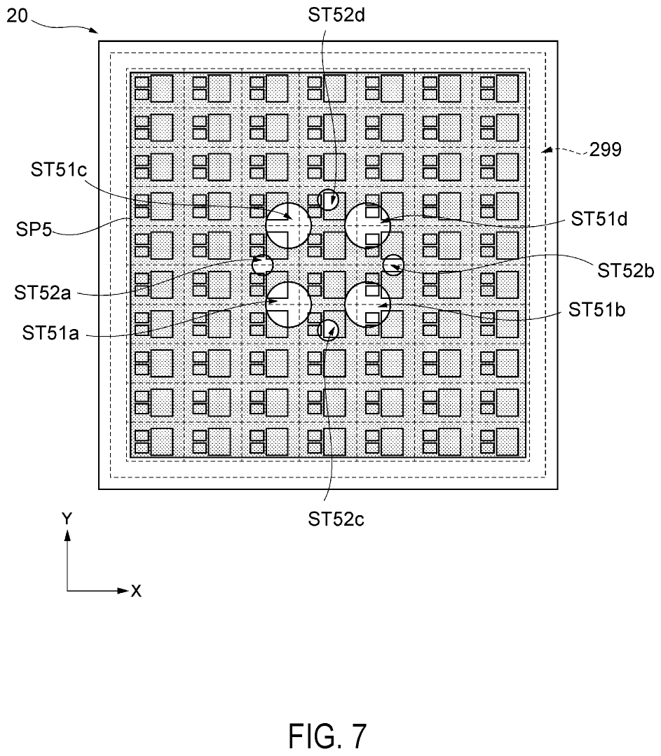

FIG. 7 is a plan view schematically illustrating a modification of a sheet resin set in a resin molding die. In plan view, a sheet resin SP5 is formed in a rectangular shape, like the sheet resin SP3 illustrated in FIG. 5. Four penetrating holes ST51a, ST51b, ST51c, ST51d and four penetrating holes ST52a, ST52b, ST52c, ST52d are formed in a central portion of the sheet resin SP5. The four penetrating holes ST51a to ST51d are of substantially equal size. The four penetrating holes ST52a to ST52d are of substantially equal size smaller than the size of each of the four penetrating holes ST51a to ST51d. The penetrating hole ST51a and the penetrating hole ST51b are arranged side by side in the X-axis direction, and the penetrating hole ST51c and the penetrating hole ST51d are arranged side by side in the X-axis direction. The penetrating hole ST51a and the penetrating hole ST51c are arranged side by side in the Y-axis direction, and the penetrating hole ST51b and the penetrating hole ST51d are arranged side by side in the Y-axis direction. The penetrating hole ST51a and the penetrating hole ST51d are arranged side by side on one diagonal line of the sheet resin SP5, and the penetrating hole ST51b and the penetrating hole ST51c are arranged side by side on the other diagonal line of the sheet resin SP5. The penetrating hole ST52a and the penetrating hole ST52b are arranged side by side on a bisector of a side of the sheet resin SP5 extending in the Y-axis direction. The penetrating hole ST52c and the penetrating hole ST52d are arranged side by side on a bisector of a side of the sheet resin SP5 extending in the X-axis direction. Accordingly, the amount of decrease of resin in a portion along a diagonal line of the sheet resin SP5 is greater than the amount of decrease of resin in a portion along a bisector of each side. In the sheet resin SP5 before the penetrating holes ST51a to ST51d and ST52a to ST52d are formed, the amount of resin in the portion along the diagonal line is greater than the amount of resin in the portion along the bisector. By forming the penetrating holes ST51a to ST51d and ST52a to ST52d of different sizes, the amount of flow of the sheet resin SP5 during heating and compression can be made uniform.

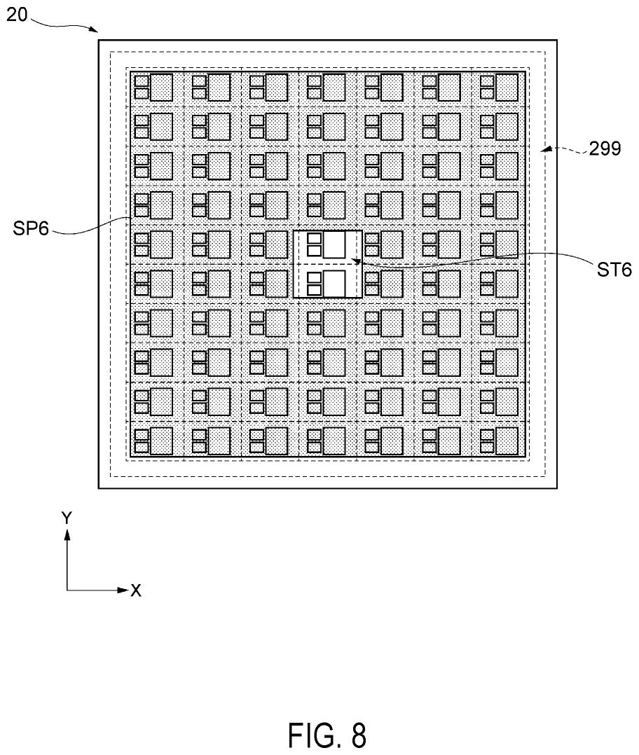

FIG. 8 is a plan view schematically illustrating a modification of a sheet resin set in a resin molding die. In plan view, a sheet resin SP6 is formed in a rectangular shape, like the sheet resin SP3 illustrated in FIG. 5. One penetrating hole ST6 of a rectangular shape is formed in a central portion of the sheet resin SP6. That is, the penetrating hole ST6 and the sheet resin SP6 are similar in shape. The sheet resin SP6 has a set of sides extending in the X-axis direction and facing each other in the Y-axis direction and a set of sides extending in the Y-axis direction and facing each other in the X-axis direction. The penetrating hole ST6 also has similar sides. A direction in which each side of the penetrating hole ST6 extends may be inclined from the X-axis direction and the Y-axis direction. The penetrating hole ST6 may be arranged inclined at an angle of 45 degrees relative to, for example, the center of the sheet resin SP6 from the arrangement illustrated in FIG. 8, or may be arranged inclined at any angle.

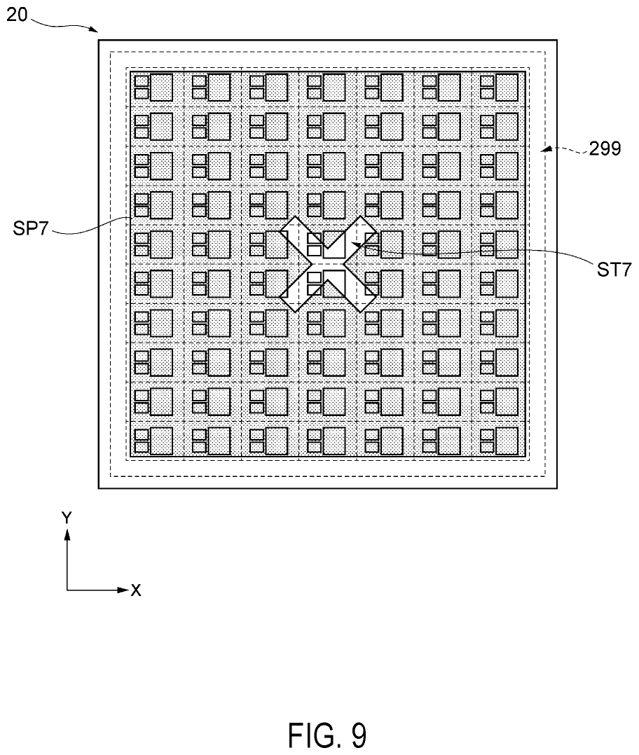

FIG. 9 is a plan view schematically illustrating a modification of a sheet resin set in a resin molding die. In plan view, a sheet resin SP7 is formed in a rectangular shape, like the sheet resin SP3 illustrated in FIG. 5. One penetrating hole ST7 of an oblique cross shape is formed in a central portion of the sheet resin SP7. That is, the penetrating hole ST7 has a shape in which rectangles having a long side along a diagonal line of the sheet resin SP7 intersect. Accordingly, the amount of decrease of resin in a portion along the diagonal line of the sheet resin SP7 is greater than the amount of decrease of resin in a portion along a bisector of each side of the sheet resin SP7, and the amount of flow of the sheet resin SP7 during heating and compression can be made uniform.

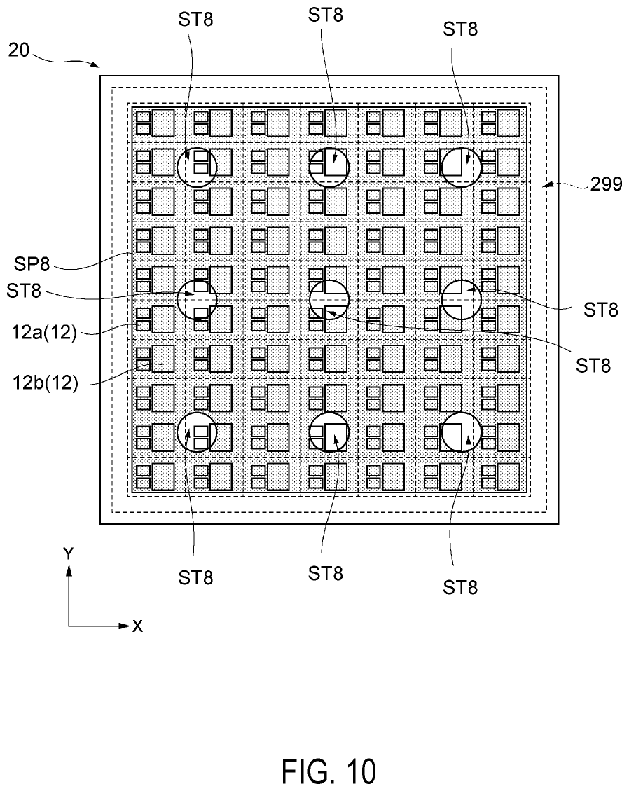

FIG. 10 is a plan view schematically illustrating a modification of a sheet resin set in a resin molding die. In plan view, a sheet resin SP8 is formed in a rectangular shape, like the sheet resin SP3 illustrated in FIG. 5. A plurality of penetrating holes ST8 are formed in the sheet resin SP8. By the plurality of penetrating holes ST8, the amount of resin in a central portion and a peripheral portion of the sheet resin SP8 is decreased. An edge of the plurality of penetrating holes ST8 overlaps any of a plurality of components 12. The plurality of penetrating holes ST8 are arranged at equal intervals. Since there is no need to adjust the position of the penetrating hole ST8 relative to the central portion of the sheet resin SP8 or relative to the plurality of components 12, formation of the plurality of penetrating holes ST8 is easier than formation of the penetrating hole ST1 illustrated in FIG. 2. For example, the plurality of penetrating holes ST8 may be already formed in a resin film that is wound around a resin roll before being fed. In this case, the sheet resin SP8 cut out from the resin film can be set in a resin molding die without change.

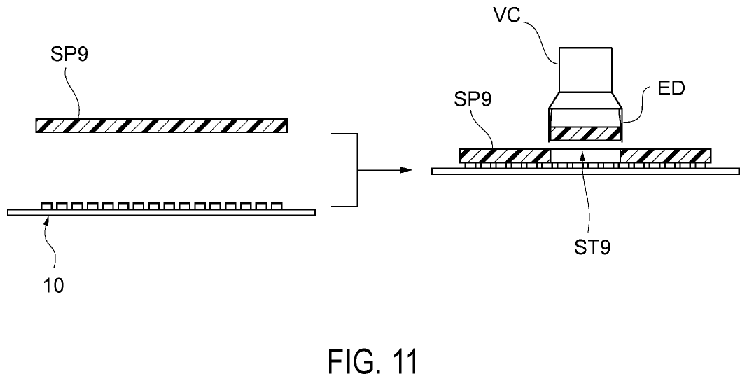

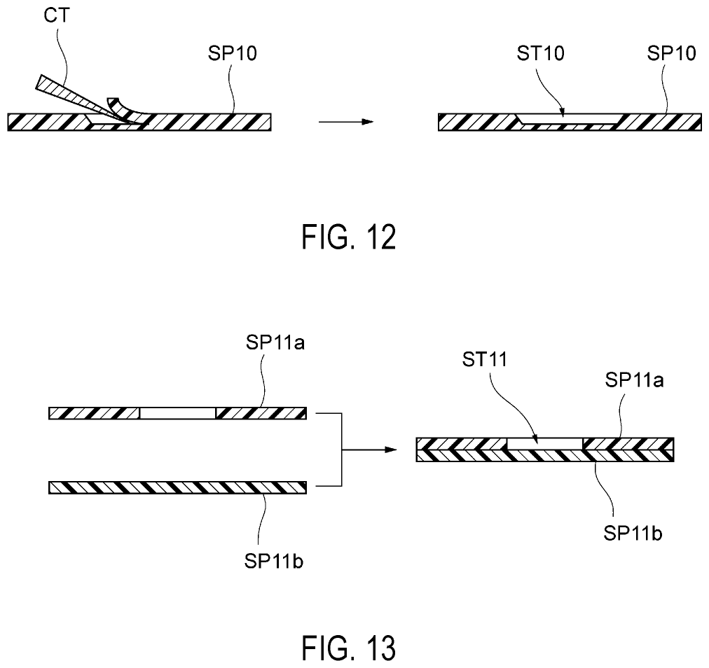

FIG. 11 schematically illustrates an example of a method for forming a penetrating hole. A penetrating hole ST9 illustrated in FIG. 12 is formed by making a cut into a sheet resin SP9 by an edge ED, sucking and lifting an area where the cut was made with a vacuum VC and removing the area. A step of forming the penetrating hole ST9 is performed, for example, after laminating the sheet resin SP9 on the workpiece 10. However, the sheet resin SP9 may be laminated on the workpiece 10 after the penetrating hole ST9 is formed.

FIG. 12 schematically illustrates an example of a method for forming a recess. FIG. 13 schematically illustrates an example of a method for forming a recess. If the amount of resin is less in a central portion of a sheet resin than in a peripheral portion of the sheet resin in plan view, a recess instead of a penetrating hole may be formed in the central portion. A recess ST10 illustrated in FIG. 12 is formed by cutting a sheet resin SP10. A recess ST11 illustrated in FIG. 13 is formed by laminating a sheet resin SP11a that has a penetrating hole formed therein on a sheet resin SP11b that is flat. The cutting may be performed using a single cutting tool as illustrated in the figure, or may be performed using a continuous cutting tool such as an end mill.

As described above, according to one aspect of the present invention, a resin-sealing method and a resin-sealing device can be provided in which variation in package dimensions can be reduced.

The embodiments described above are for facilitating the understanding of the present invention rather than for limiting the interpretation of the present invention. Each element included in the embodiments and its arrangement, material, condition, shape, size, and the like are not limited to those illustrated and can be appropriately changed. It is possible to partially replace or combine the configurations shown in different embodiments.

### DESCRIPTION OF REFERENCE NUMERALS

1: resin-sealing device; 10: workpiece; 11: carrier; 12: component; 100: resin supply device; FR: feed roll; PR: pinch roll; CT: sheet cutter; PN: mechanical punch; SP1: sheet resin; ST1: penetrating hole; 190: resin molding die; 191: lower die; 192: upper die; 199: cavity.

1. A resin-sealing method that compression molds a resin on a workpiece having a plurality of components mounted on a carrier and manufactures a plurality of packages in each of which at least one of the plurality of components is sealed with resin, the resin-sealing method comprising:
setting a sheet resin in a resin molding die; and
compression molding the sheet resin set in the resin molding die,
wherein
at least one penetrating hole or recess is formed in a central portion of the sheet resin so that amount of resin is less in the central portion of the sheet resin than in a peripheral portion of the sheet resin in plan view.

2. The resin-sealing method according to claim 1, further comprising:
feeding a resin film of an elongated shape;
cutting out the sheet resin from the resin film; and
forming the at least one penetrating hole or recess in the resin film or the sheet resin.

3. The resin-sealing method according to claim 1, wherein
the at least one penetrating hole is formed by punching.

4. The resin-sealing method according to claim 1, wherein
the at least one penetrating hole is formed by sucking an area where a cut has been made.

5. The resin-sealing method according to
claim 1, wherein
a cavity of the resin molding die has a circular shape; and
the sheet resin has a rectangular shape whose diagonal length is equal to or less than a diameter of the cavity.

6. The resin-sealing method according to claim 1, wherein
the sheet resin has a rectangular shape; and
amount of decrease of resin in a portion along a diagonal line of the sheet resin due to the at least one penetrating hole or recess is greater than amount of decrease of resin in a portion along a bisector of each side of the sheet resin due to the at least one penetrating hole or recess.

7. The resin-sealing method according to claim 1, wherein
the at least one penetrating hole or recess is one penetrating hole or recess; and
the one penetrating hole or recess and the sheet resin are similar in shape in plan view.

8. The resin-sealing method according to claim 1, wherein,
in setting the sheet resin in the resin molding die, the sheet resin is laminated on the workpiece to be sealed with resin.

9. The resin-sealing method according to claim 1, wherein,
in setting the sheet resin in the resin molding die, the sheet resin is laminated on a release film.

10. A resin-sealing method that compression molds a resin on a workpiece having a plurality of components mounted on a carrier and manufactures a plurality of packages in each of which at least one of the plurality of components is sealed with resin, the resin-sealing method comprising:
setting a sheet resin in a resin molding die; and
compression molding the sheet resin set in the resin molding die,
wherein
a plurality of penetrating holes or recesses are formed over an entire surface of the sheet resin in plan view; and
an edge of the plurality of penetrating holes or recesses of the sheet resin set in the resin molding die overlaps any of the plurality of components.

11. A resin-sealing device that compression molds a resin on a workpiece having a plurality of components mounted on a carrier and manufactures a plurality of packages in each of which at least one of the plurality of components is sealed with resin, the resin-sealing device comprising:
a sheet cutting part, cutting out a sheet resin from a resin film of an elongated shape;
a reducing part, forming at least one penetrating hole or recess in the resin film or the sheet resin; and
a resin molding die, compression molding the sheet resin that has been set,
wherein
the at least one penetrating hole or recess is formed in a central portion of the sheet resin so that amount of resin is less in the central portion of the sheet resin than in a peripheral portion of the sheet resin in plan view.
